(19) United States
(12) Patent Application Publication
(10) Pub. No.: US 2013/0019924 A1
(43) Pub. Date: Jan. 24, 2013

(54) Nanoscopically Thin Photovoltaic Junction Solar Cells

(71) Applicants: Michael J. Naughton, Chestnut Hill, MA (US); Krzysztof J. Kempa, Chestnut Hill, MA (US); Zhifeng Ren, Newton, MA (US)

(72) Inventors: Michael J. Naughton, Chestnut Hill, MA (US); Krzysztof J. Kempa, Chestnut Hill, MA (US); Zhifeng Ren, Newton, MA (US)

(73) Assignee: The Trustees of Boston College

(21) Appl. No.: 13/512,132

(22) PCT Filed: Nov. 24, 2010
(86) PCT No.: PCT/US10/58073

§ 371 Date: Sep. 10, 2012

Related U.S. Application Data
(60) Provisional application No. 61/264,332, filed on Nov. 25, 2009.

(51) Int. Cl. H01L 31/0248; H01L 31/0376; H01L 31/042; H01L 31/0264

(52) U.S. Cl. 136/249; 136/252; 136/258; 136/244

(57) ABSTRACT

Nanoscopically thin photovoltaic junction solar cells are disclosed herein. In an embodiment, there is provided a photovoltaic film 100 that includes a p-doped region 102, an n-doped region 106, and an intrinsic region 104 positioned between the p-doped region 102 and the n-doped region 106, wherein an overall thickness of the photovoltaic film is between about 15 nm to about 30 nm so as to extract hot carriers excited across a band gap, wherein the extracted hot carriers are capable of resulting in an open circuit voltage, Voc, of the photovoltaic film that increases with optical frequency, and wherein the extracted hot carriers are capable of resulting in a total short-circuit current density, Jsc, between about 4 mA/cm² and about 8 mA/cm².

### RELATED APPLICATIONS

This application claims the benefit of and priority to U.S. Provisional Patent Application No. 61/264,332, filed on Nov. 25, 2009, the entirety of this application is hereby incorporated herein by reference.

### FIELD

The embodiments disclosed herein relate to nanoscopically thin photovoltaic junctions, and more particularly to ultra-thin p-i-n hydrogenated amorphous silicon photovoltaic junctions showing detectable and useful hot electron effects.

### BACKGROUND

Photovoltaics (PV), now a billion-dollar industry, is experiencing staggering growth as increased concerns over fuel supply and carbon emissions have encouraged governments and environmentalists to become increasingly prepared to offset the extra cost of solar energy. Photovoltaic solar cells convert solar light photons into electricity. Photovoltaic solar cells convert solar energy into electrical energy by several steps: collection of solar radiation in a light-absorbing, semiconducting material; photogeneration of charge carriers (electron-hole pairs) by exchange of incident photon energy with an electron in a semiconductor valence band sufficient to move that electron to the conduction band (leaving behind a positively-charged vacancy, or hole); and transportation of the liberated charge carriers to a metallic contact that will transmit the electricity as current. The electrons and holes will interact with other electrons and holes through carrier-carrier interactions to form carrier populations that can be described by a Boltzmann distribution. At this point, the temperature defining the carrier distribution is generally above the lattice temperature and hence the carriers are referred to as hot charge carriers (hot electrons and holes). Studied for more than 50 years, from Gunn diodes to integrated circuit diagnostics, hot electrons are anticipated to play an important role in high efficiency PV. Usually, in a typical solar cell, the hot electrons will give off their excess energy, i.e., the energy of electrons relative to the bottom of the conduction band, or of holes relative to the top of the valence band, to the lattice by producing optical phonons. These optical phonons then interact with other phonons and the excess energy is lost as heat. In most bulk semiconductors, all of this happens in less than 0.5 picoseconds.

One of the seminal concepts proposed for next-generation solar cells involves harvesting the excess energy of the hot electrons before the excess energy is dissipated as heat (phonons). While early investigations in electrolyte-semiconductor junctions found some evidence for hot electron injection into the electrolyte, it is believed that no device has been shown to exhibit improved photovoltaic action associated with hot electrons. Even with improved hot carrier lifetimes in current quantum PV systems, the distance the hot carriers can travel before cooling is likely to be short about 1 nanometer.

### SUMMARY

Nanoscopically thin photovoltaic junction solar cells are disclosed herein. According to aspects illustrated herein, there is provided a photovoltaic film that includes a p-doped region; an n-doped region; and an intrinsic region positioned between the p-doped region and the n-doped region, wherein an overall thickness of the photovoltaic film is between about 15 nm to about 30 nm so as to extract hot carriers excited across a band gap, wherein the extracted hot carriers are capable of resulting in an open circuit voltage, V_{oc}, of the photovoltaic film that increases with optical frequency, and wherein the extracted hot carriers are capable of resulting in a total short-circuit current density, J_{SC}, between about 4 mA/cm² and about 8 mA/cm². In an embodiment, the photovoltaic film further comprises a first selective energy filter disposed between the p-doped material and the intrinsic region and a second selective energy filter disposed between the n-doped material and the intrinsic region.

According to aspects illustrated herein, there is provided a solar cell that includes an array of nano-coaxial structures, wherein each nano-coaxial structure comprises a metallized nanopillar surrounded by a nanoscopically thin photovoltaic film located adjacent to a side of the nanopillar, and a transparent conducting coating located adjacent to a side of the nanoscopically thin photovoltaic film, wherein the nanoscopically thin photovoltaic film comprises a p-doped region; an n-doped region; and an intrinsic region positioned between the p-doped region and the n-doped region, wherein an overall thickness of the nanoscopically thin photovoltaic film is between about 15 nm to about 30 nm so as to extract hot carriers excited across a band gap, wherein the extracted hot carriers are capable of resulting in an open circuit voltage, V_{oc}, of the nanoscopically thin photovoltaic film that increases with optical frequency, and wherein a short-circuit current density, J_{sc}, of each nano-coaxial structure ranges between about 4 mA/cm² and about 8 mA/cm².

According to aspects illustrated herein, there is provided a solar panel that includes an interconnected assembly of solar cells, wherein at least some of the solar cells in the assembly include one or more layers of a nanoscopically thin photovoltaic film deposited on a substrate, where a transparent conducting oxide layer forms a front electrical contact and a metal layer forms a rear contact, wherein the nanoscopically thin photovoltaic film comprises a p-doped region; an n-doped region; and an intrinsic region positioned between the p-doped region and the n-doped region, wherein an overall thickness of the nanoscopically thin photovoltaic film is between about 15 nm to about 30 nm so as to extract hot carriers excited across a band gap, wherein the extracted hot carriers are capable of resulting in an open circuit voltage, V_{oc}, of the nanoscopically thin photovoltaic film that increases with optical frequency, and wherein a short-circuit current density, J_{sc}, of each of the solar cells including the nanoscopically thin photovoltaic film ranges between about 4 mA/cm² and about 8 mA/cm².

### BRIEF DESCRIPTION OF THE DRAWINGS

The presently disclosed embodiments will be further explained with reference to the attached drawings, wherein like structures are referred to by like numerals throughout the several views. The drawings shown are not necessarily to scale, with emphasis instead generally being placed upon illustrating the principles of the presently disclosed embodiments.

FIG. 1 is a schematic diagram of an embodiment of a p-i-n photovoltaic film of the present disclosure having an overall thickness of between about 15 nm to about 30 nm.

FIG. 2 is a schematic diagram of an embodiment of a p-i-n photovoltaic film of the present disclosure having an overall thickness of between about 15 nm to about 30 nm.

FIG. 3 is a schematic diagram of an embodiment of a solar cell that may be fabricated using a p-i-n photovoltaic film of the present disclosure having an overall thickness of between about 15 nm to about 30 nm.

FIG. 4 is a schematic diagram of an embodiment of an array of solar cells that may be fabricated using a nanoscopically thin p-i-n photovoltaic film of the present disclosure.

FIG. 5A and FIG. 5B present images of a solar cell fabricated using a nanoscopically thin p-i-n photovoltaic film of the present disclosure.

FIG. 6 shows a schematic view of an embodiment of a solar cell of the present disclosure having an array of nano-coaxial structures, wherein each nano-coaxial structure includes a metallized nanopillar surrounded by a nanoscopically thin p-i-n photovoltaic film of the present disclosure located adjacent to a side of the nanopillar, and a transparent conducting coating located adjacent to a side of the nanoscopically thin photovoltaic film.

FIG. 7 are graphs illustrating the current-voltage characteristics of a nanoscopically thin a-Si:H p-i-n solar cell of the present disclosure.

FIG. 8 is a graph illustrating the open-circuit voltage (V_{oc}) change versus overall junction thickness for a nanoscopically thin a-Si:H p-i-n solar cell of the present disclosure.

FIG. 9 is a graph illustrating the variations of short circuit current density (J_{SC}) with overall junction thickness for a-Si:H p-i-n solar cells of the present disclosure.

FIG. 10A and FIG. 10B are energy band diagrams of a conventional thick p-i-n junction (FIG. 10A) and a nanoscopically thin a-Si:H p-i-n photovoltaic film of the present disclosure (FIG. 10B).

FIG. 11 presents profilometry data for a nanoscopically thin a-Si:H photovoltaic film of the present disclosure having an overall junction thickness, D, of about 15 nm.

FIG. 12 presents data for optical absorption coefficient α for a-Si:H over a portion of the visible spectrum.

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

### DETAILED DESCRIPTION

As used herein, the terms “hot carriers” or “hot electrons” refer to either holes or electrons that have gained very high kinetic energy after being accelerated by a strong electric field in areas of high field intensities within a semiconductor device.

As used herein, the term “band gap” refers to the energy difference between the top of the valence band and the bottom of the conduction band.

As used herein, the term “optical frequency” refers to the frequency (v or f) of the absorbed light or the photon frequency. The optical frequency is related to the energy as follows: E=hv, wherein E is the energy of a photon, h is Planck's constant, and v is the frequency of a photon (frequency of a photon's associated electromagnetic wave). Equivalently, the energy E may be represented as E= [symbol] ω), wherein E is the energy of a photon, [symbol] =h/2π and ω is the angular frequency of a photon.

As used herein, the terms “nanoscopically thin” and “ultra-thin” refer to photovoltaic junctions or photovoltaic films (the terms photovoltaic junctions or photovoltaic films may be used interchangeably throughout the instant application) having an overall junction thickness between about 1 nanometer (nm) to about 1000 nm. In an embodiment, a nanoscopically thin photovoltaic junction of the present disclosure has an overall junction thickness between about 10 nm to about 310 nm. In an embodiment, a nanoscopically thin photovoltaic junction of the present disclosure has an overall junction thickness between about 10 nm to about 40 nm. In an embodiment, a nanoscopically thin photovoltaic junction of the present disclosure has an overall junction thickness between about 15 nm to about 30 nm. In an embodiment, a nanoscopically thin photovoltaic junction of the present disclosure has an overall junction thickness of about 40 nm. In an embodiment, a nanoscopically thin photovoltaic film of the present disclosure has an overall junction thickness of about 15 nm.

As used herein, the term “short-circuit current” or “I_{SC}” refers to the current through a solar cell when the voltage across the solar cell is zero (i.e., when the solar cell is short circuited). The short-circuit current is due to the generation and collection of light-generated carriers (cold carriers and hot carriers). For an ideal solar cell at most moderate resistive loss mechanisms, the short-circuit current and the light-generated current are identical. Therefore, the short-circuit current is the largest current which may be drawn from the solar cell. The short-circuit current depends on a number of factors, including, the area of the solar cell (to remove the dependence of the solar cell area, it is more common to list the short-circuit current density, J_{SC} in mA/cm², rather than the short-circuit current), the number of photons (i.e., the power of the incident light source), the spectrum of the incident light (for most solar cell measurement, the spectrum is standardized to the AM 1.5 spectrum), the optical properties (absorption and reflection) of the solar cell, and the collection probability of the solar cell. When comparing solar cells of the same material type, the most critical material parameter is the diffusion length and surface passivation. In an embodiment, when a nanoscopically thin photovoltaic film of the present disclosure is used to fabricate a solar cell, the solar cell has measured short-circuit current density, J_{SC}, between about 4 mA/cm² and about 8 mA/cm².

As used herein, the term “open-circuit voltage” or “V_{oc}” refers to the maximum voltage available from a solar cell or a photovoltaic film, and this occurs at zero current. The open-circuit voltage corresponds to the amount of forward bias on the solar cell due to the bias of the solar cell junction with the light-generated current. V_{oc} depends on the saturation current (I₀) of the solar cell and the light-generated current (I_{L}). The saturation current, I₀ depends on recombination in the solar cell. Open-circuit voltage is then a measure of the amount of recombination in the device. Conventional silicon solar cells on high quality single crystalline material have open-circuit voltages of up to 730 mV under one sun and AM 1.5 conditions, while commercial devices on multicrystalline silicon typically have open-circuit voltages around 600 mV. In an embodiment, a nanoscopically thin photovoltaic junction of the present disclosure generates open-circuit voltages between about 0.75 V and about 1 V. In an embodiment, when a nanoscopically thin photovoltaic junction of the present disclosure is used to fabricate a solar cell, the solar cell has measured open-circuit voltages between about 0.75 V and about 1 V.

As used herein, the term “fill factor” or “FF” is a parameter which, in conjunction with V_{oc} and I_{SC}, determines the maximum power from a solar cell or a photovoltaic film. The FF is defined as the ratio of the maximum power from the solar cell to the product of V_{oc} and I_{sc}. Graphically, the FF is a measure of the “squareness” of the solar cell and is also the area of the largest rectangle which will fit in the IV curve.

As used herein, the term “efficiency” or “η” refers to the ratio of energy output from a solar cell to input energy from the sun. In addition to reflecting the performance of the solar cell itself, the efficiency depends on the spectrum and intensity of the incident sunlight and the temperature of the solar cell. Therefore, conditions under which efficiency is measured must be carefully controlled in order to compare the performance of one device to another. Terrestrial solar cells are measured under AM 1.5 conditions and at a temperature of 25° C. Solar cells intended for space use are measured under AM 0 conditions. The efficiency of a solar cell is determined as the fraction of incident power which is converted to electricity. In an embodiment, when a nanoscopically thin photovoltaic junction of the present disclosure is used to fabricate a solar cell, the solar cell has an efficiency between about 2.0% and about 8.0%. In an embodiment, when a nanoscopically thin photovoltaic junction of the present disclosure is used to fabricate a solar cell, the solar cell has an efficiency between about 2.4% and about 4.0%.

As used herein, the term “quantum efficiency” or “QE” refers to the ratio of the number of charge carriers collected by a solar cell or a photovoltaic film to the number of photons of a given energy shining on the solar cell. QE therefore relates to the response of a solar cell to the various wavelengths in the spectrum of light shining on the cell. The QE is given as a function of either wavelength or energy. Two types of QE of a solar cell are often considered: External Quantum Efficiency (EQE) is the ratio of the number of charge carriers collected by the solar cell to the number of photons of a given energy shining on the solar cell from outside; and Internal Quantum Efficiency (IQE) is the ratio of the number of charge carriers collected by the solar cell to the number of photons of a given energy that shine on the solar cell from outside and are not reflected back by the cell, nor penetrate through. The IQE is always larger than the EQE.

As used herein, the term “nano-coaxial structure” refers to a nano-coaxial transmission line, which consists of a plurality of concentric layers. In an embodiment, the nano-coaxial structure has three concentric layers: an internal core electrode/conductor, a semiconducting or dielectric coating around the core, and an outer electrode/conductor. In an embodiment, transmission of electromagnetic energy inside the coaxial line is wavelength-independent and happens in transverse electromagnetic (TEM) mode. In an embodiment, the internal core conductor is a metallic core. In an embodiment, the outer conductor is a metallic shielding, such as, for example, a transparent conductive oxide coating.

As used herein, the terms “nanotubes,” “nanowires,” “nanorods,” “nanocrystals,” “nanoparticles,” “nanopillars,” and “nanostructures” which are employed interchangeably herein, are known in the art. To the extent that any further explanation may be needed, these terms primarily refer to material structures having sizes, e.g., characterized by their largest dimension, in a range of a few nanometers (nm) to about a few microns. In applications where highly symmetric structures are generated, the sizes (largest dimensions) can be as large as tens of microns.

According to aspects illustrated herein, there is provided nanoscopically thin photovoltaic films showing detectable and useful hot electron effects. In an embodiment, a nanoscopically thin photovoltaic junction of the present disclosure is a p-i-n (positively-doped layer—intrinsic, undoped layer—negatively-doped layer) hydrogenated amorphous silicon (a-Si:H) film having an overall junction thickness ranging from about 10 nm to about 200 nm. In an embodiment, a nanoscopically thin photovoltaic junction of the present disclosure is a p-i-n hydrogenated amorphous silicon (a-Si:H) film having an overall junction thickness ranging from about 15 nm to about 30 nm. In an embodiment, a nanoscopically thin photovoltaic junction of the present disclosure is semitransparent. In an embodiment, a nanoscopically thin photovoltaic junction of the present disclosure is ultra-lightweight. In an embodiment, a nanoscopically thin photovoltaic junction of the present disclosure is flexible. In an embodiment, a nanoscopically thin photovoltaic junction of the present disclosure generates electricity. In an embodiment, a nanoscopically thin photovoltaic junction of the present disclosure is capable of generating electricity in both natural and artificial light conditions. In an embodiment, a nanoscopically thin photovoltaic junction of the present disclosure generates power.

In an embodiment, the present disclosure relates to the fabrication of ultra-thin amorphous silicon p-i-n junction photovoltaic films having nanoscopically thin n and p regions, nanoscopically thin i regions, large internal electric fields (for example, about 10⁸ V/m), large short-circuit currents (J_{SC}) for a solar cell fabricated from such films and translucency properties, making these photovoltaic films useful in applications, including, but not limited to, solar cells/panels, solar windows (for example, a spray on coating) and solar paint (e.g., color of the car paint can be visible through the cell).

In an embodiment, the open circuit voltage in solar cells fabricated from nanoscopically-thin p-i-n amorphous films of the present disclosure may increase with optical frequency (light frequency), potentially due to the extraction of hot carriers. In an embodiment, the ultrathin nature of these cells may also lead to a large electric field, reducing carrier recombination and facilitating larger than expected current/current density in addition to the increased voltage. In an embodiment, the ultrathin nature of these cells leads to multiple exciton generation (MEG), or carrier multiplication, which may further increase power conversion efficiency of the solar cell, and thus the current density in the cell. The larger than expected current density (J_{SC}) indicates improved carrier extraction despite reduced optical absorption for ultrathin absorber layers. In an embodiment, the overall power conversion efficiency is at least 2.5% with absorbers less than 1/20th as thick as conventional a-Si solar cells.

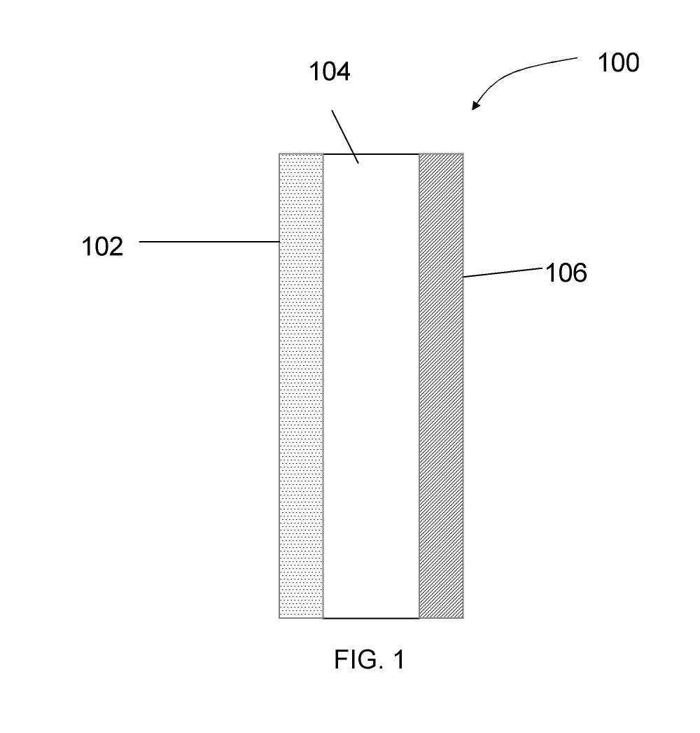

In one aspect, there is provided a nanoscopically thin p-i-n junction photovoltaic film. Referring to FIG. 1, a nanoscopically thin p-i-n junction photovoltaic film 100 is comprised of a doped or undoped p-region 102, a doped or undoped i-region 104, and a doped or undoped n-region 106. In an embodiment, the thickness of the p-region and the n-region ranges from about 2 nm to about 10 nm. In an embodiment, the p-region and the n-region may have the same thickness and the i-region may be thicker than the p-region and the n-region. In an embodiment, the p-region and the n-region may each be about 5 nm thick. The thickness d of the intrinsic i-region varies between about 5 nm and about 300 nm. In an embodiment, the thickness d of the intrinsic i-region is between about 5 nm and about 30 nm.

In an embodiment, the overall junction thickness D may range from about 15 nm to about 200 nm. In another embodiment, the overall film thickness D may range from about 10 nm to about 30 nm. In yet another embodiment, the overall film thickness D is between about 15 nm and about 25 nm. In yet another embodiment, the overall junction thickness D is about 15 nm and a solar cell fabricated from such film has a J_{SC} of about 4.9 mA/cm², a V_{oc} of about 0.79 V, a FF of about 66% and a η of about 2.6%. In an embodiment, the overall film thickness D is about 25 nm and a solar cell fabricated from such film has a J_{SC} of about 5.3 mA/cm², a V_{oc} of about 0.81 V, a FF of about 69% and a 11 of about 2.9%.

In an embodiment, an i-region of a p-i-n junction of the present disclosure may be formed from an amorphous semiconducting material, such as, for example, silicon (a-Si) or its alloys, without dopants or with one or more dopants. In amorphous semiconducting materials, due to the disordered nature of the material, some atoms may have a dangling bond, which defects in the continuous random network and may cause anomalous electrical behavior. In an embodiment, an amorphous semiconducting material may contain hydrogen atoms, halogen atoms or both. These atoms can bind to dangling bonds to improve the mobility and lifetime of carriers in the i-region. Moreover, these atoms may also act to compensate interfacial energy levels of the interfaces between the i-region and the p-region and between the i-region and the n-region and improve the photovoltaic effect of photovolatic, photoelectric currents and photo-responsibility of the photovoltaic cells. In an embodiment, an i-region of a p-i-n junction of the present disclosure may be formed from hydrogenated a-Si, or a-Si:H. In an embodiment, an i-region of a p-i-n junction of the present disclosure may be formed from a semiconducting material having a band gap from about 0.5 eV to about 2.5 eV.

In an embodiment, a p-region and a n-region of a p-i-n junction photovoltaic film of the present disclosure may be formed from an amorphous semiconducting material as described above to which one or more dopants has been added to increase the number of free charge carriers, positive in case of the p-region and negative in case of the n-region. In an embodiment, the p-region of a p-i-n junction photovoltaic film of the present disclosure comprises an amorphous semiconducting material doped with a group III atom, such as B, Al, Ga, In or Tl. In an embodiment, the n-region of a p-i-n junction photovoltaic film of the present disclosure comprises an amorphous semiconducting material doped with a group IV atom, such as P, As, Sb or Bi. In an embodiment, the amount of dopant in the p-region and the n-region of a p-i-n junction photovoltaic film of the present disclosure may range between about 0.1 atom % to about 50 atom %.

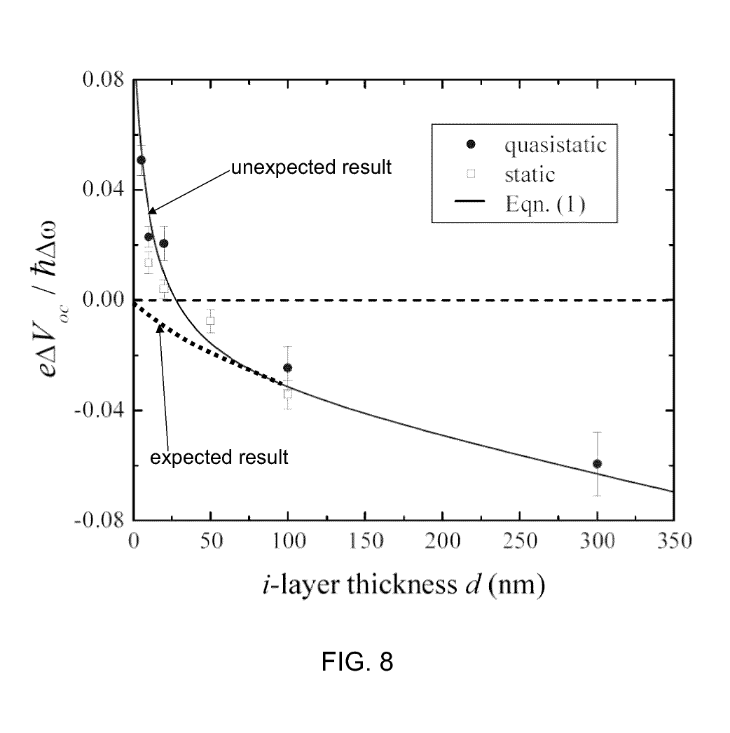

Hot carriers (hot electrons and hot holes) are characterized by high effective temperatures. Because hot carriers are photo excited above the band gap, hot carriers come in with a higher voltage than the band gap. However, in a photovoltaic film of conventional thickness, hot carriers cool down to the band gap energy before the excess energy of hot carriers can be captured. As a result, a significant percentage of the original kinetic energy of hot carriers is lost. In contrast, because p-i-n photovoltaic films of the present disclosure are nanoscopically thin, these films allow harvesting the excess energy of hot carriers. In the p-i-n photovoltaic films of the present disclosure, the hot carriers are harnessed to contribute to the current of the voltage prior to getting the conventional cooling. As a result, open-circuit voltage (V_{oc}) relative to its value in a photovoltaic film of conventional thickness increases, thereby increasing the energy conversion efficiency of p-i-n photovoltaic films of the present disclosure above that achievable without contribution from hot carriers, as illustrated for example in FIG. 8 and as described below.

That is, there appears a positive difference in open circuit voltage (V_{oc}) between illumination with high energy (blue) light and illumination with low energy (red or green) light. In general, higher energy light creates more and hotter hot electrons, which after thermalization generate more heat, as compared to lower energy photons. This high energy light therefore elevates the temperature of the solar cell with respect to the ambient more than does the lower energy light. The open circuit voltage (V_{oc}) of a solar cell typically decreases as temperature increases, regardless of color/energy of incident light. As a result, a typical situation is that V_{oc} for blue light is lower than V_{oc} for red light, such that ΔV_{oc} is negative, as shown in FIG. 8 for i-layer thickness greater that about 50 nm. An expected result would be a continuation of this large-thickness line to ΔV_{oc}=0 at zero thickness, as indicated in FIG. 8. On the contrary, an unexpected result is observed for ultrathin layers: ΔV_{oc} becomes positive for d less than about 50 nm, indicating that, in spite of the excess heat generated by higher energy photons, some higher energy (hot) electrons and holes are leaving the cell into to the cell contacts at higher than expected open circuit voltage. The unexpected portion of the result is so indicated in FIG. 8.

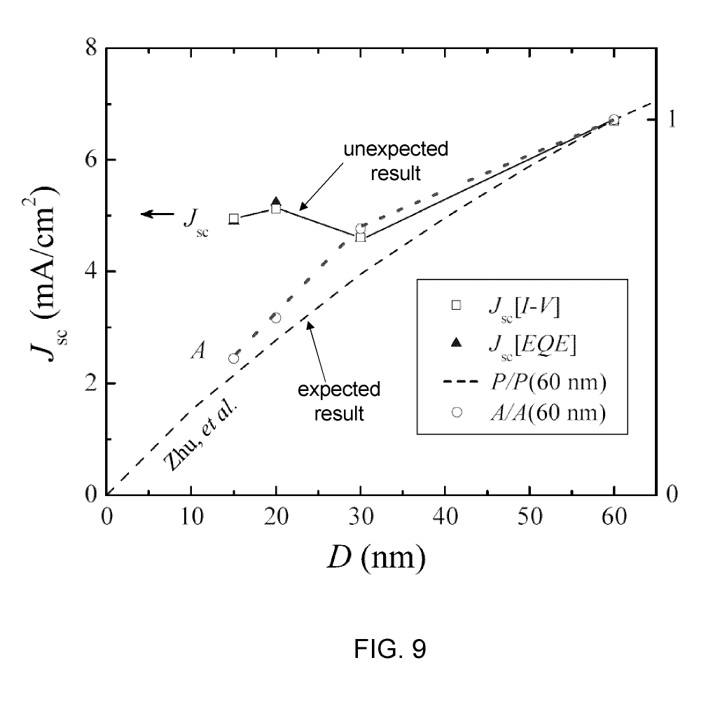

Up to now, however, it was believed that, solar cells fabricated from thin photovoltaic films would not be able to generate desired current density, if any, because thin photovoltaic films could not absorb enough light. In general, as the thickness of a photovoltaic material in a solar cell decreases, the material absorbs less light, and the short-circuit current density in the solar cell was conventionally-anticipated to also decrease toward zero. However, Applicants have unexpectedly discovered that below a certain thickness, the current density becomes independent of optical absorption. That is, the current density stops decreasing even though the amount of light absorption continues to decrease due to the decrease in film thickness as illustrated for example in FIG. 9 and as described below. This indicates that there is an improved extraction of carriers for ultra-thin layers, sufficiently strong to overcome the reduced light absorption, resulting in overall power conversion efficiency improvement over a conventionally-thick PV film. Further, with improved light trapping schemes, such as via nanowire configurations and nano-coaxial configurations, ultra-thin hot-electron solar cells could be engineered with significant increases in efficiency.

By way of a non-limiting example, in an embodiment, ultra-thin n- and p-doped regions may each be about 5 nm thick, and the thickness d of the intrinsic i-region may vary between about 5 nm and about 300 nm in order to achieve the hot carrier. The total film thickness was thus D=d+10 nm. In an embodiment, the overall film thickness D ranges from about 10 nm to about 310 nm. In an embodiment, the overall film thickness D ranges from about 10 nm to about 40 nm. In an embodiment, the overall film thickness D is about 15 nm and a solar cell fabricated from such cell has a J_{SC} of about 4.9 mA/cm², a V_{oc} of about 0.79 V, a FF of about 66% and a η of about 2.6%. In an embodiment, the overall film thickness D is about 25 nm and a solar cell fabricated from such film has a J_{SC} of about 5.3 mA/cm², a V_{oc} of about 0.81 V, a FF of about 69% and a η of about 2.9%.

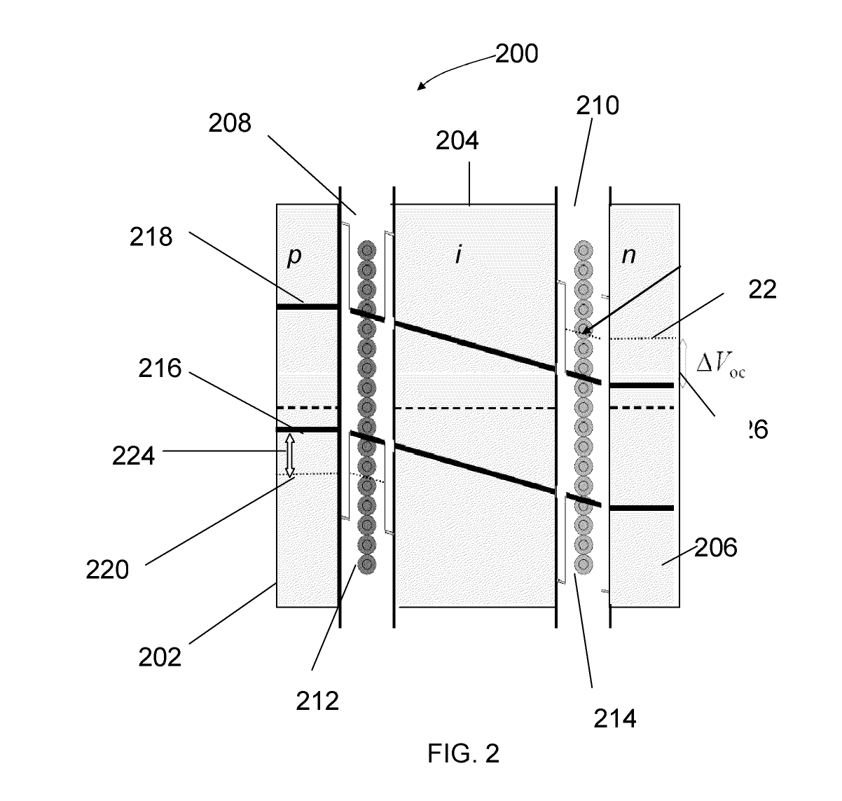

Referring to FIG. 2, in an embodiment, a nanoscopically thin p-i-n junction 200 of the present disclosure includes selective energy filters (SEF) 212 and 214 disposed at a p-i interface 208 between an i-region 204 and a p-region 202 and at an i-n interface 210 between the i-region 204 and an n-region 206, respectively, forming a quantum well. As shown in FIG. 2, the selective energy filter 212 may comprise materials that allow electrons to pass between regions at a quantized energy level 220 below the valence band edge depicted by line 216 and the selective energy filter 214 may comprise materials that allow electrons to pass between regions at a quantized energy 222 level above the conduction band edge depicted by line 218. Setting the energy level above the conduction band and below the valence band may facilitate extraction of hot carriers, hot electrons and/or hot holes with high energy, resulting in an increase in V_{oc} by the difference in energy (ΔV_{oc}) represented by arrows 224 and 226. In an embodiment, quantum dots may be used as selective energy filters. The energy levels of quantum dots is tunable by their composition and size of the core and/or shell if present. Quantum dots suitable for this application, include, but are not limited to, core-shell type quantum dots, such as, for example, CdSe/ZnS, CdSe/ZnSe, and core type quantum dots, such as, for example, PbS, PbSe, and Si. In an embodiment, a solar cell fabricated from an ultrathin p-i-n a-Si:H photovoltaic film of the present disclosure, without energy selective filters, has a V_{oc} ranging from about 0.75 to 1.0V, a FF ranging from about 50% to 80%, and a J_{sc} ranging from about 5 to 10 mA/cm². In an embodiment, a solar cell fabricated from an ultrathin p-i-n a-Si:H photovoltaic film of the present disclosure, with energy selective filters, has a V_{oc} ranging from about 0.8 to 1.3V, a FF ranging from about 50% to 80%, and a J_{sc} ranging from about 5 to 10 mA/cm². In contrast, in an embodiment, a solar cell fabricated from a conventional p-i-n a-Si:H thick photovoltaic cell, has a V_{oc} ranging from about 0.75 to 1.0V, a FF ranging from about 50% to 80%, and a J_{sc} ranging from about 10 to 15 mA/cm².

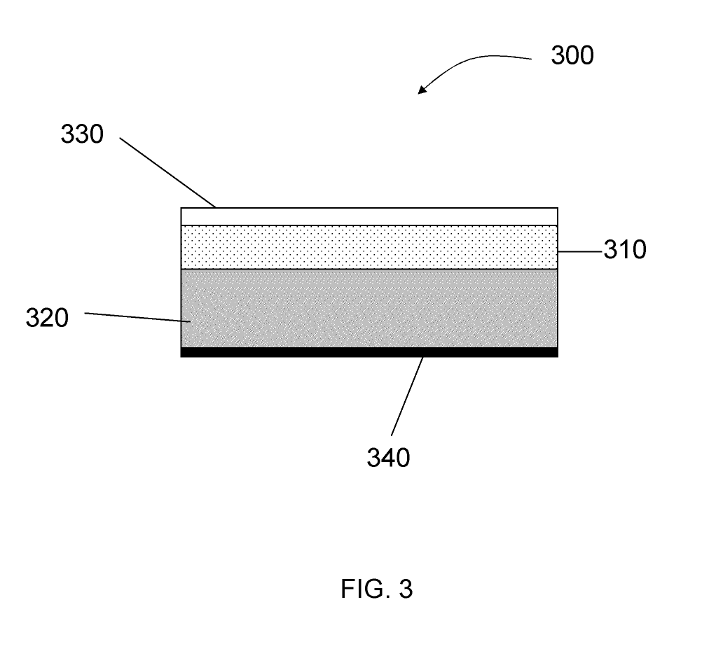

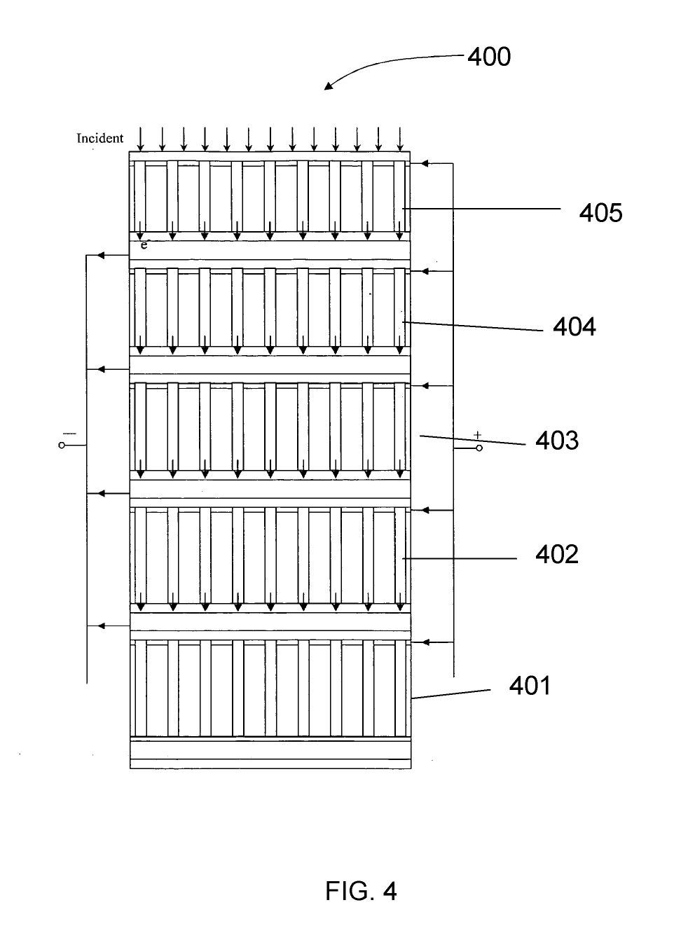

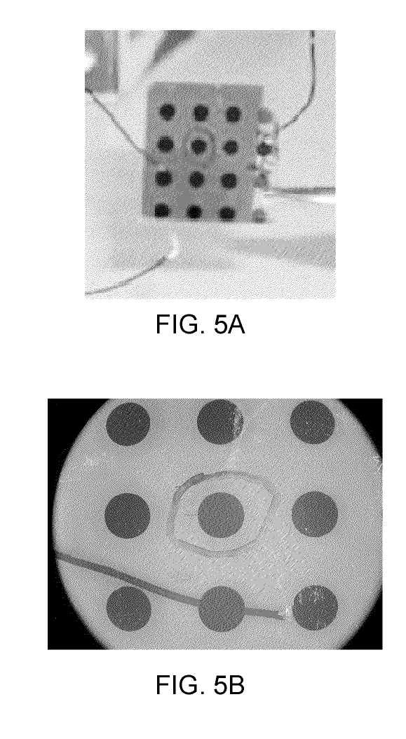

In another aspect, there is provided a nanoscopically thin film solar cell fabricated using a nanoscopically thin p-i-n photovoltaic (PV) film of the present disclosure. As illustrated in FIG. 3, in an embodiment a solar cell 300 of the present disclosure generally comprises a nanoscopically thin PV film 310 of the present disclosure deposited on a substrate 320, where a transparent conducting oxide layer (such as indium tin oxide (ITO)) forms a front electrical contact 330 of the solar cell, and a metal layer forms the rear contact 340. In order to increase the absorption efficiency of a nanoscopically thin film solar cell of the present disclosure, tandem or multi-layer devices that include nanoscopically thin PV film of the present disclosure may be stacked one on top of the other. Referring to FIG. 4, in an embodiment, a solar cell array 400 may be assembled from a plurality of solar cells 401-405 that include nanoscopically thin PV film of the present disclosure with the front and back of adjacent cells can be directly interconnected in series, using, for example aluminum contacts. In an embodiment, one or more layers of a nanoscopically thin PV film of the present disclosure may be deposited on an ITO-coated boroalumino-silicate glass substrates with back contacts made using 100 nm thick aluminum, thermally evaporated through a mask to define 3 mm diameter contacts, as shown in FIG. 5A and FIG. 5B. In an embodiment, the overall junction thickness D, which ranges from about 15 nm to about 310 nm or from about 15 nm to about 30 nm, is ultra-thin so as to result in all of the electron-hole pairs being generated close to the energy selective contacts to ensure the hot carriers do not cool before being collected.

Suitable materials for the substrate include, but are not limited to, glass, such as borosilicate glass; polymers, such as SU-8, polyimide, polyethylene naphthalate (PEN), polyethylene terephthalate (PET), or metals, such as stainless steel or aluminum. The deposition of the nanoscopically thin PV film onto the substrate may be achieved using any known technique in the art. In an embodiment, the PV film may be deposited on the substrate using a chemical vapor deposition method (CVD). In CVD, gaseous mixtures of chemicals are dissociated at high temperature (for example, CO₂ into C and O₂). This is the “CV” part of CVD. Some of the liberated molecules may then be deposited on a nearby substrate (the “D” in CVD), with the rest pumped away. Examples of CVD methods include but not limited to, “plasma enhanced chemical vapor deposition” (PECVD), “hot filament chemical vapor deposition” (HFCVD), and “synchrotron radiation chemical vapor deposition” (SRCVD).

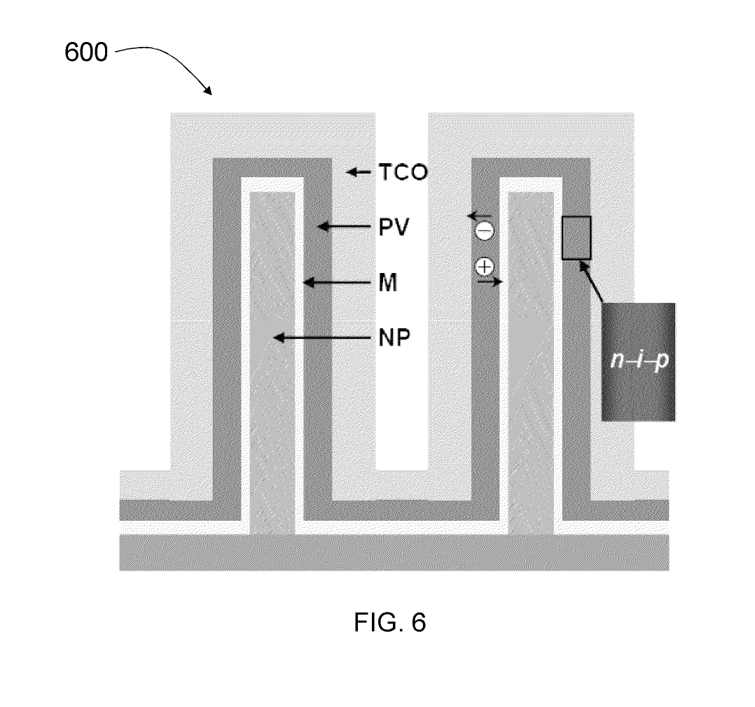

In an embodiment, a nanoscopically thin PV film of the present disclosure is combined with an efficient light-trapping technology, such as, for example, nanowire structures or nano-coaxial structures, to yield a solar cell that is optically thick and electronically ultra-thin. In an embodiment, a solar cell of the present disclosure that is optically thick and electronically ultra-thin comprises an array of aligned nanopillars made of a conductive material or having a metal coating (“the internal electrode”), a layer of a nanoscopically thin PV film of the present disclosure (“the absorber layer”, and a transparent conducting oxide layer (“the outer electrode”) arranged as a nano-coaxial structure. FIG. 6 shows a schematic view of an embodiment of an optically thick, electronically ultra-thin solar cell of the present disclosure including a plurality of nano-coaxial structures. The nano-coaxial structure includes an internal electrode that is coated with a nanoscopically thin p-i-n film of the present disclosure. Although not illustrated, in an embodiment, the internal electrode includes an impedance-matched optical nano-antenna and a coaxial section. The optical nano-antenna can provide efficient light collection. An outer electrode surrounds the nanoscopically thin p-i-n film. In an embodiment, the nano-coaxial structures are embedded in a conductive matrix. The internal electrode may be a metallic core. Examples of metals for the internal electrodes include but are not limited to, carbon fiber; carbon nanotube; pure transition metals such as nickel (Ni), aluminum (Al), or chromium (Cr); metal alloys, e.g. stainless steel (Fe/C/Cr/Ni) or aluminum alloys (Al/Mn/Zn); and metallic polymers. Other internal electrodes are highly doped semiconductors, and semi-metals (metals with vanishingly small band gap, e.g. graphite). Those skilled in the art will recognize that the internal electrode may be other conducting materials known in the art and be within the spirit and scope of the presently disclosed embodiments. In yet other embodiments, the internal electrode may be made of a non-conductive nanopillar material, and thus a conductive layer may be disposed between the internal electrode NP and the nanoscopically thin p-i-n film PV of the present disclosure.

The outer electrode may be a metal or a metal oxide. Examples of outer electrodes include, but are not limited to, carbon fiber; carbon nanotube; transparent conductive oxides such as indium tin oxide, fluorine doped tin oxide and doped zinc oxide; pure transition metals such as nickel (Ni), aluminum (Al), or chromium (Cr); metal alloys e.g. stainless steel (Fe/C/Cr/Ni) or aluminum alloys (Al/Mn/Zn); and metallic polymers. In an embodiment, the outer electrode is a thin transparent conductive oxides, such as indium-tin oxide.

Other outer electrodes are highly doped semiconductors, and semi-metals (metals with vanishingly small band gap, e.g. graphite). Those skilled in the art will recognize that the outer electrode may be other conducting materials known in the art and be within the spirit and scope of the presently disclosed embodiments. In yet other embodiments, the outer electrode 160 may be made of a non-conducting materials coated with a conducting material such as, for example, thin metal oxide.

In an embodiment, nano-thin p-i-n photovoltaic films of the present disclosure are sufficiently thin to enable the extraction of a density of hot carriers sufficient to increase V_{oc} relative to its value in conventionally-thick solar cells. In other words, the average V_{oc} of a ultrathin photovoltaic film of the present disclosure is about 0.75 to about 1 V, which is about the same or even higher than the average V_{oc} of a conventionally thick photovoltaic film, which is about 0.8v, even though the ultrathin film uses a lot less material. Accordingly, the energy conversion efficiency of a ultrathin photovoltaic film of the present disclosure is higher than that of a conventionally thick cell. In an embodiment, the V_{oc} of a ultrathin photovoltaic film of the present disclosure may be further increased to between about 0.8 to about 1.3 V by including selective energy filters, as described above. On the other hand, including selective energy filters into a conventionally thick film will have minimal, if any, effect on the V_{oc} because the fraction of extractable hot electrons in a conventionally thick film is much less, if not zero, than in a ultrathin photovoltaic film of the present disclosure.

In an embodiment, nanoscopically thin p-i-n photovoltaic films of the present disclosure are sufficiently thin to enable solar cells fabricated from such films to generate an internal electric field that is sufficiently large to enable the extraction of charge carriers as electrical current in excess of that achievable with the smaller internal electric fields generated in conventionally-thick junctions. In an embodiment, the hot carriers extracted by a ultrathin photovoltaic film of the present disclosure are capable of resulting in an electric field that reduces carrier recombination so as to result in a short-circuit current density higher than expected in a solar cell fabricated from an ultrathin photovoltaic film of the present disclosure. In an embodiment, the hot carriers extracted by a ultrathin photovoltaic film of the present disclosure are capable of resulting in a multiple excitation generation so as to result in a higher than expected short-circuit density in a solar cell fabricated from an ultrathin photovoltaic film of the present disclosure. In an embodiment, a short-circuit current density, J_{sc}, of a solar cell fabricated from an ultrathin photovoltaic film of the present invention ranges between about 4 mA/cm² and about 8 mA/cm². In another embodiment, a short-circuit current density, J_{sc}, of a solar cell fabricated from an ultrathin photovoltaic film of the present invention ranges between about 4 mA/cm² and about 9 mA/cm². In yet another embodiment, a short-circuit current density, J_{sc}, of a solar cell fabricated from an ultrathin photovoltaic film of the present invention ranges between about 4 mA/cm² and about 10 mA/cm².

In an embodiment, a nanoscopically thin PV film of the present disclosure may be used as a coating on glass windows, plastics, and other see-through structures to supply electric power to homes, businesses or transportation vehicles. In an embodiment, a nanoscopically thin PV film of the present disclosure can be used as a coating on fabrics to supply electric power to clothing, backpacks, and other items. In an embodiment, a nanoscopically thin PV film of the present disclosure can be used as a coating on tents to supply power for soldiers in the field. Such a coating would add negligible weight to the tent. Since the density of α-Si is about 2 gm/cm³, a PV coating of the present disclosure with the total thickness of 30 nm only weighs about 6 micrograms per square centimeter. In another embodiment, a nanoscopically thin PV film of the present disclosure can be used as the photovoltaic material in a building-integrated photovoltaic (BIPV) module. BIPV modules are photovoltaic materials that are used to replace conventional building materials in parts of the building envelope such as the roof, skylights, or facades. BIPV modules are available in several forms, including, but not limited to, flat roofs, pitched roofs, facade and glazing. BIPV modules are increasingly being incorporated into the construction of new buildings as a principal or ancillary source of electrical power, although existing buildings may be retrofitted with BIPV modules as well. The advantage of integrated photovoltaics over more common non-integrated systems is that the initial cost can be offset by reducing the amount spent on building materials and labor that would normally be used to construct the part of the building that the BIPV modules replace. In addition, since BIPV are an integral part of the design, they generally blend in better and are more aesthetically appealing than other solar options. BIPV coated with a nanoscopically thin PV film of the present disclosure may generate a maximum power of about 0.5 MW, if placed on a building with the outside surface area of about 10,000 square meters.

In an embodiment, a nanoscopically thin PV film of the present disclosure is used as a scavenger cell, absorbing light that would otherwise not be absorbed and converting that light energy to electricity. In an embodiment, a nanoscopically thin PV film of the present disclosure can be laid over a pool of water and collect the visible energy photovoltaically while still allowing the infrared (IR) light to pass through. With a band gap of a-Si of about 1.7 eV, nanoscopically thin films of the present disclosure are largely transparent to IR radiation, while still collecting visible light (RGB) to generate electrical power. The pass-through IR would be absorbed by water and produce thermal heat.

In an embodiment, a nanoscopically thin PV film of the present disclosure may be coupled with materials that can harness energy outside the visible, or the red-green-blue, photon spectrum. In an embodiment, there are provided linear or nono-coaxial solar cells as described above in which thermal cells may be disposed below one or more layers of a nanoscopically thin PV film of the present disclosure. Thermaphotovoltaic (TPV) cells would harness energy in the longer wavelength spectrum and convert it to thermal energy, i.e. heat, or electricity. As noted above, photovoltaic films of the present disclosure collect visible light but pass-through IR radiation, which can be collected by a TPV cell.

In another aspect, the present disclosure provides a method for designing nanoscopically thin photovoltaic (PV) p-i-n junctions for capturing the excess energy of hot carriers. In an embodiment, the relationship between V_{oc} and the thickness d of the i-region is:

$$\frac{e Δ {V}_{oc}}{ℏ Δ ω} = \frac{{D}_{c}}{D} + α + β D$$

Where [symbol] is Planck's constant, ω is the photon frequency, and e is the electron charge, D is the total junction thickness (D=d+the combined thickness of the doped regions p and n), and D_{c}, α and β are adjustable constants. Graphs may be generated for fixed current densities J_{sc}, which can obtained by varying the intensities of light sources employed to obtain fixed currents I. Values for the constants D_{c}, α and β can then be derived using a least squares fit to the experimental data to be used for designing p-i-n junctions capable of capturing the excess energy of hot carriers. Constant D_{c}, is a characteristic length scale over which hot carriers are capable of travelling before emitting phonons and losing energy (cooling).

In an embodiment, a photovoltaic film includes a p-doped region; an n-doped region; and an intrinsic region positioned between the p-doped region and the n-doped region, wherein an overall thickness of the photovoltaic film is between about 15 nm to about 30 nm so as to extract hot carriers excited across a band gap, wherein extracted hot carriers are capable of resulting in an open circuit voltage, V_{oc}, of the photovoltaic film that increases with optical energy, and wherein extracted hot carriers are capable of resulting in an electric field that reduces carrier recombination so as to result in a short-circuit current density, J_{sc}, of between about 4 mA/cm² and about 8 mA/cm² for a solar cell fabricated from the photovoltaic film.

In an embodiment, a solar cell includes an array of nano-coaxial structures, wherein each nano-coaxial structure comprises a metallized nanopillar surrounded by a nanoscopically thin photovoltaic film located adjacent to a side of the nanopillar, and a transparent conducting coating located adjacent to a side of the nanoscopically thin photovoltaic film, wherein the nanoscopically thin photovoltaic film comprises a p-doped region; an n-doped region; and an intrinsic region positioned between the p-doped region and the n-doped region, wherein an overall thickness of the photovoltaic film is between about 15 nm to about 30 nm so as to extract hot carriers excited across a band gap, wherein extracted hot carriers are capable of resulting in an open circuit voltage, V_{oc}, of the photovoltaic film that increases with optical energy, and wherein extracted hot carriers are capable of resulting in an electric field that reduces carrier recombination so as to result in a short-circuit current density, J_{sc}, in each nano-coaxial structure of between about 4 mA/cm² and about 8 mA/cm².

In an embodiment, a solar panel includes an interconnected assembly of solar cells, wherein at least some of the solar cells in the assembly include one or more layers of a nanoscopically thin photovoltaic film deposited on a substrate, where a transparent conducting oxide layer forms a front electrical contact and a metal layer forms a rear contact, wherein the nanoscopically thin photovoltaic film comprises a p-doped region; an n-doped region; and an intrinsic region positioned between the p-doped region and the n-doped region, wherein an overall thickness of the photovoltaic film is between about 15 nm to about 30 nm so as to extract hot carriers excited across a band gap, wherein extracted hot carriers are capable of resulting in an open circuit voltage, V_{oc}, of the photovoltaic film that increases with optical energy, and wherein extracted hot carriers are capable of resulting in an electric field that reduces carrier recombination so as to result in a short-circuit current density, J_{sc}, in each of the solar cells including the nanoscopically thin photovoltaic film of between about 4 mA/cm² and about 8 mA/cm².

The present disclosure is described in the following Examples, which are set forth to aid in the understanding of the disclosure, and should not be construed to limit in any way the scope of the disclosure as defined in the claims which follow thereafter. The following examples are put forth so as to provide those of ordinary skill in the art with a complete disclosure and description of how to make and use the present disclosure, and are not intended to limit the scope of what the inventors regard as their invention nor are they intended to represent that the experiments below are all or the only experiments performed. Efforts have been made to ensure accuracy with respect to numbers used (e.g. amounts, temperature, etc.) but some experimental errors and deviations should be accounted for. Unless indicated otherwise, parts are parts by weight, molecular weight is weight average molecular weight, temperature is in degrees Centigrade, and pressure is at or near atmospheric.

### EXAMPLES

Solar cells were fabricated from nanoscopically thin p-i-n hydrogenated amorphous silicon (a-Si:H) junctions of the present disclosure were prepared on indium-tin-oxide (ITO, 200 nm thick)-coated boroalumino-silicate glass substrates, and silicon deposition was done via plasma-enhanced chemical vapor deposition at about 200° C. using silane (SiH₄) and H₂ gases for the intrinsic/absorber i-layer, with diborane (B₂H₆) and phosphine (PH₃) gases additionally employed for p- and n-doping, respectively. Back contacts were made using 100 nm thick aluminum, thermally-evaporated through a mask to define 3 mm-diameter contacts, completing each solar cell. Silicon thicknesses for each of the p, i and n-layer depositions were calibrated using atomic force microscopy and profilometry, and cross-checked by directly measuring D on a portion of each sample separate from that used for the PV measurements, using profilometry.

Current-voltage (I-V) data was taken under simulated terrestrial solar illumination (AM 1.5) and under monochromatic light using red, green and blue lasers. In the laser experiments, light intensities were adjusted to establish a wavelength-independent short-circuit current I_{sc}, and V(I) and/or V_{oc} were recorded at the different optical wavelengths for each sample (each thickness d).

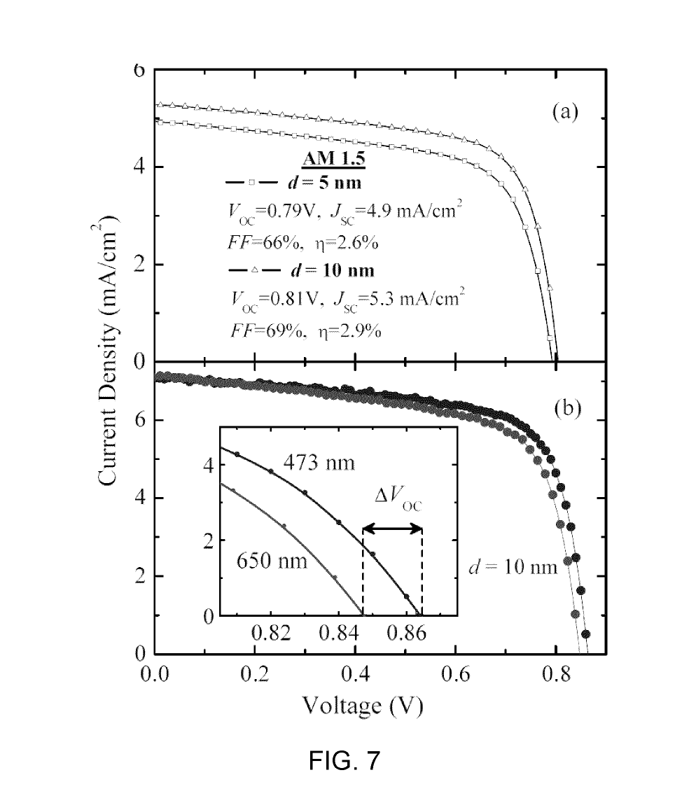

FIG. 7 shows representative I-V data for samples under typical standard “Air Mass 1.5” (AM 1.5) illumination in the PV regime, here for i-layer samples having d of approximately 5 nm and 10 nm (overall junction thickness, D, of approximately 15 nm and 20 nm, respectively) (top panel (a)). The data demonstrates the high quality of the PV junctions, even with the ultra-thin, 5 nm-thick n- and p-layers. The D=15 nm sample achieved over 2.5% power conversion efficiency. Similar data were taken not under AM 1.5 light, but under monochromatic laser light using lasers obtained from RGBLaser LLC. I-V data for the d=10 nm sample for blue (λ=473 nm) and red (λ=650 nm) illumination, is illustrated in the bottom panel (b) with each laser intensity adjusted (via a diffusing lens) to assure the same I_{sc} (and thus short-circuit current density J_{sc}). It can be seen that there is an increase in V_{oc} for higher energy light over that of lower energy, with ΔV_{oc}=V_{oc}^{blue}−V_{oc}^{red}=(16.7±1.1) mV. Similar I-V data was taken for samples with d=5, 20, 50, 100 and 300 nm and ΔV_{oc} was extracted for each sample. To eliminate possible artifacts due to quasi-static transients (laser instabilities, ohmic heating, etc.), quasi-static measurements for all samples and lasers were performed in parallel using a set-up that assures collection of data with rapid switching between open circuit voltage V_{oc} and closed circuit current I_{sc} configurations. The results were in excellent agreement with the static results based on the complete I-V data, showing that the quasi-static transients are negligible.

Combined results from all experiments involving lasers are shown in FIG. 8. ΔV_{oc} obtained as above as well as via V_{oc}^{blue}−V_{oc}^{green} is divided (normalized) by the difference in the corresponding photon energies per charge [symbol] Δω/e to obtain the y-axis in FIG. 8. Here h is Planck's constant, ω is the photon frequency, and e is the electron charge. FIG. 8 shows the normalized ΔV_{oc} as a function of d, for fixed J_{SC}=7.1 mA/cm². Symbols represent the mean values, and error bars are obtained from the standard deviations. In these data, the intensity of each laser (color) employed was adjusted to obtain a fixed I_{sc} of 0.5 mA, corresponding to a fixed J_{SC} of 7.1 mA/cm² after dividing by the area of each 3 mm diameter cell. The difference in laser frequencies Δω in the normalization factor [symbol] Δω/e was calculated using the laser wavelengths λ for each laser and the relation ω=2πc/λ, where c is the speed of light, with Δω the difference between ω's of different wavelengths (different color laser). With the employed normalization, the data congregate around a single line, which has the following, phenomenological form:

$$\frac{e Δ {V}_{oc}}{ℏ Δ ω} = \frac{{D}_{c}}{D} + α + β D \qquad ( 1 )$$

where [symbol] Δω/e=2.62 eV−2.2 eV=0.42 eV (for blue-green data), and [symbol] Δω/e=2.62 eV−1.91 eV=0.71 eV (for blue-red data), and the adjustable constants are D_{c}=1.3 nm, α=−0.03, and β=−1.2×10⁻⁴ nm⁻¹. D_{c} is believed to be a “critical distance” from the p-i junction and p-n junction over which hot carriers can be extracted. The constant β likely parameterizes the temperature dependence of V_{oc}. The total junction thickness D is the sum of the thickness of the i-region (d) and the thicknesses of the p-region and the n-region.

As seen in FIG. 8, ΔV_{oc} is positive for ultra-thin junctions (d˜5 nm), decreases monotonically with i-layer thickness d, and becomes negative for d>30 nm. This effect is quantitatively captured by Eq. (1) above, and is explained by the following discussion. Hot electrons are generated by photons with energy [symbol] ω>E_{g}, where E_{g} is the energy gap of the absorbing semiconductor. These hot electrons rapidly thermalize via direct phonon emission and indirect cooling via collisions with cold electrons in the doped regions, on a time scale of approximately 0.1 picoseconds. Only a small fraction, of order D_{c}/D, of these hot electrons, generated within a small distance D_{c} of the order of 1 nm away from the collector, can be extracted with their original kinetic energy ( [symbol] ω−E_{g}). The ensemble-averaged energy of the electrons arriving at the collector is therefore E_{avg}˜( [symbol] ω−E_{g})D_{c}/D, and the resulting increase of V_{oc} is

$$Δ {V}_{oc} \approx \frac{ℏΔ ω}{e} \frac{{D}_{c}}{D} .$$

This is the positive contribution which decreases monotonically with d (the first term in the right-hand side of Eq. (1), D_{c}/D). The remaining hot electrons cool off by emitting phonons, which results in a temperature increase of the junction. This increase is proportional to the initial kinetic energy of the thermalizing electrons rapidly delivering energy to the thermal bath. The temperature is also expected to increase linearly with the number of thermalizing hot electrons, which in turn is proportional to D−D_{c}≈D. This is the origin of the 3^{rd} term on the right-hand side of Eq. (1). Therefore, the temperature increment corresponding to this effect is ΔT˜ [symbol] ΔωD. It is well known that increasing temperature only reduces V_{oc} in solar cells, with typically linear dependence near room temperature, so that ΔV_{oc}˜−ΔT˜−D. Thus, hot electrons contribute to both the 1/D increase for small D and the linear decrease for large D, of V_{oc}. Combining both contributions, along with a D-independent term α (the 2^{nd} term on the right hand side of Eq. (1)) yields Eq. (1). With an empirically-determined value of D_{c}=1.3 nm, of order of the 1 nm estimate above, the solid line in FIG. 8 is obtained, which follows the measured data. This phenomenological agreement strongly supports interpretation of the data in FIG. 8 as an interplay between two competing effects: an increase of V_{oc} with light energy (i.e. ΔV_{oc}>0) in ultra-thin samples due to extracted hot electrons (a solid-state analog of the photoelectric effect), and a decrease of V_{oc} (ΔV_{oc}<0) in thicker samples associated with unextracted hot electrons losing their energy to heat.

The observation of a measurable hot electron effect in the solar cells of the present disclosure is facilitated by the exceptionally short carrier escape time, due to the nanoscopic junction thickness. This small thickness also increases the junction electric field, increasing carriers velocities. This also leads to the anomalously large current observed (as compared to that expected from thickness considerations alone): the J_{SC} of the ultra-thin film samples (d=5 to 20 nm) under 1-sun is relatively large, 5 mA/cm² (FIG. 7), already half that obtained for conventional (d˜400 nm) planar cells.

FIG. 9 is a graph illustrating the variation of short circuit current density with junction thickness. J_{SC} typically varies approximately linearly with optical absorption until the cell thickness is such that a significant fraction of incident light is absorbed. Likewise, optical absorption varies approximately linearly with absorber (cell) thickness. As a result, J_{SC} changes with absorber thickness, as indicated by the red circles and red dashed line in FIG. 9. Since solar cell output power P is directly related to J_{SC}, P should also change as the absorber thickness changes, as in the black dashed line in FIG. 9. As can be seen from FIG. 9, the integrated optical absorbance A (shown normalized to the D=60 nm value) which governs the photovoltaic current for thin films, decreases with decreasing D, as expected, because thinner junctions absorb less light. Likewise, the dashed line representing a model by Zhu et al., of converted solar power as a function of film thickness in p-i-n a-Si solar cells, falls to zero as D→0. This curve represents typical solar cell behavior.

On the other hand, in the nanoscopically thin solar cells of FIG. 9 (blue symbols), J_{sc} deviates from the conventionally-anticipated behavior, for cell thicknesses below about D=30 nm. Instead of systematically falling to zero as D decreases toward zero, J_{SC} tends to saturate at an anomalously large value of around 5 mA/cm² for D in the range 10 to 30 nm. Thus, while J_{SC} is expected to be about 1.5 mA/cm² for D=10 nm, it unexpectedly measures more than 200% more than that, due to the ultrathin nature of the solar cell. FIG. 9 shows data for both the directly-measured J_{SC} (that is, from I-V curves) and the J_{SC} values derived by integrating measurements of external quantum efficiency (EQE), which is the ratio of extracted free charge carriers to incident photons, as a function of wavelength, which is an alternate manner in which to determine J_{SC}. The two values agree in the figure. The power P and optical absorption A plotted in FIG. 9 are each normalized to their values at D=60 nm, as shown on the right-hand scale.

The data indicates that there is an improved extraction of carriers for ultra-thin layers, sufficiently strong to overcome the reduced light absorption. In an embodiment, this deviation is attributed to the high junction electric field (˜108 V/m), which varies as 1/D and serves to reduce carrier recombination, that is to reduce, or illuminate, the fraction of electron-hole pairs that recombine. The overall power conversion efficiency of these ultra-thin cells is thus enhanced by both excess voltage (hot electron effect) and excess current (high electric field effect), approaching η˜3% with absorbers less than 1/20th as thick as conventional cells. In an embodiment, this deviation is attributed to the ability of a nanoscopic junction of the present disclosure to generate multiple electron-hole pairs from the absorption of a single photon, so as to result in a multiple exciton generation (MEG), or carrier multiplication. MEG, which may considerably further increase the power conversion efficiency of the solar cell. For example, in FIG. 9, at a nanoscopic junction thickness of D of about 15 nm, an expected J_{sc} would be about 2.5 mA/cm², however, the observed J_{sc} was about 5.0 mA/cm², approximately double that of the expected result.

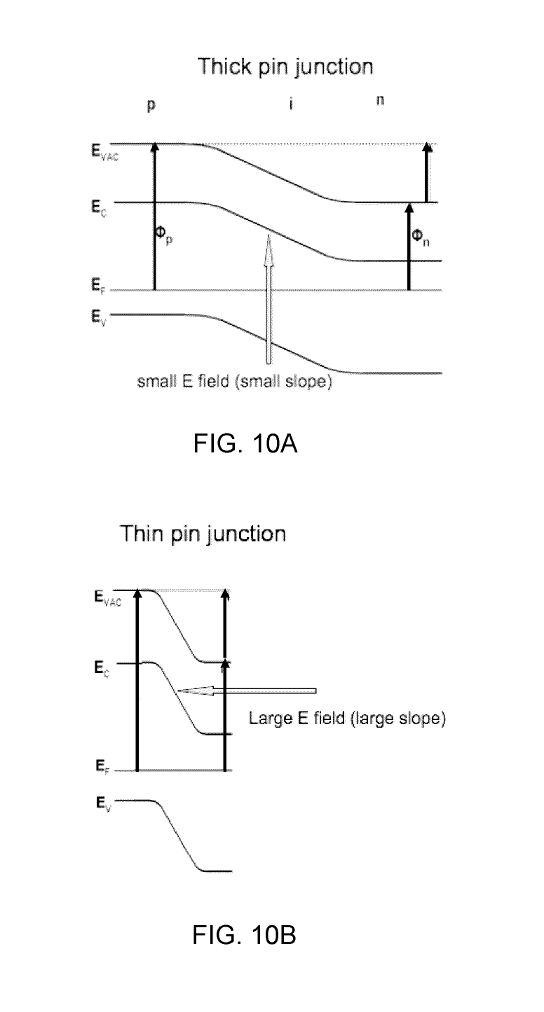

FIG. 10A and FIG. 10B are energy band diagrams of a conventional thick p-i-n junction and an ultra-thin a-Si:H p-i-n photovoltaic junction of the present disclosure. A large electric field develops inside the i region, as well as in the n and p regions of an ultra-thin a-Si:H p-i-n photovoltaic junction of the present disclosure. This field results from the ultra-thin device thickness (the same voltage V drops over a much smaller distance D, as so E=V/D is large, since D is small).

The open circuit voltage V_{oc} in ultra-thin a-Si:H p-i-n solar cells of the present disclosure increases with light energy. The observed increase is due to extraction of a residual population of hot electrons generated near the collector. The effect naturally changes sign for thick junctions, as hot electrons thermalize to the lattice and warm the junction. In addition to the observed hot electron-induced voltage changes, the ultra-thin nature of the photovoltaic junctions of the present disclosure leads to large internal electric fields, yielding reduced recombination and increased current. A phenomenological argument provides a qualitative understanding of these effects, and gives guidelines for designing future, high-efficiency, hot electron solar cells.

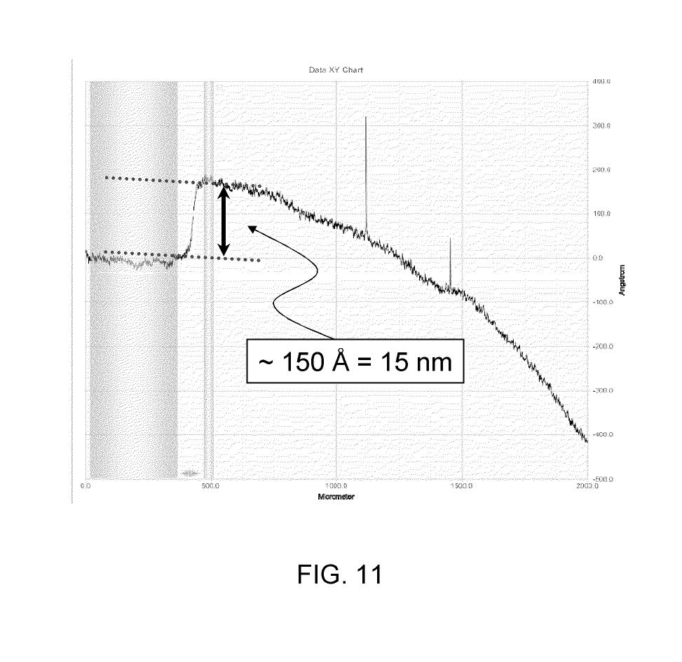

FIG. 11 is profilometry data for a D=15 nm thick a-Si:H solar cell, showing a step from the substrate to the silicon deposited area. The height of the step shows that the total thickness (p+i+n) of this particular solar cell was indeed 15 nm.

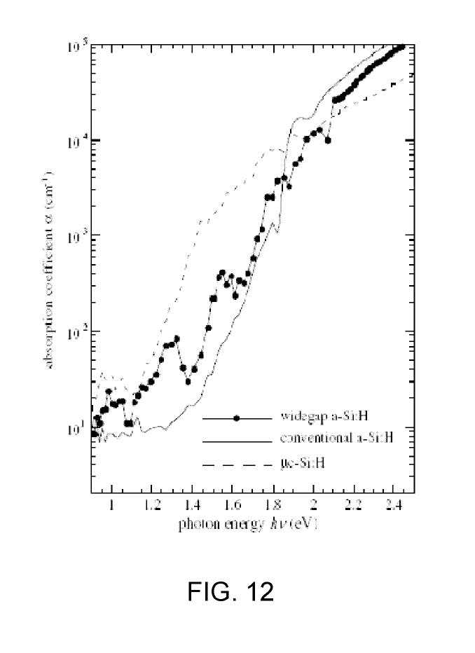

FIG. 12 provides data for optical absorption coefficient α for a-Si:H over a portion of the visible spectrum. This data was reported in Yoshida, et al., J. Non-Cryst. Sol. 354 2164 (2008). FIG. 12 shows that optical absorption is strong on the short wavelength (high energy) part of the solar spectrum, and relatively weak in the long wavelength (low energy) portion.

All patents, patent applications, and published references cited herein are hereby incorporated by reference in their entirety. It will be appreciated that several of the above-disclosed and other features and functions, or alternatives thereof, may be desirably combined into many other different systems or application. Various presently unforeseen or unanticipated alternatives, modifications, variations, or improvements therein may be subsequently made by those skilled in the art.

What is claimed is:

1. A photovoltaic film comprising:
a p-doped region;
an n-doped region; and
an intrinsic region positioned between the p-doped region and the n-doped region,
wherein an overall thickness of the photovoltaic film is between about 15 nm to about 30 nm so as to extract hot carriers excited across a band gap,
wherein the extracted hot carriers are capable of resulting in an open circuit voltage, V_{oc}, of the photovoltaic film that increases with optical frequency, and
wherein the extracted hot carriers are capable of resulting in a total short-circuit current density, J_{sc}, between about 4 mA/cm² and about 8 mA/cm².

2. The photovoltaic film of claim 1 wherein the p-doped region, the n-doped region and the intrinsic region form a hydrogenated amorphous silicon (a-Si:H) junction.

3. The photovoltaic film of claim 1 wherein the overall thickness of the photovoltaic film is about 15 nm so as to result in a short-circuit current density, J_{SC}, of about 4.9 mA/cm², an open-circuit voltage, V_{oc}, of about 0.79 V, a fill factor, FF, of about 66% and an overall power conversion efficiency, η, of about 2.6%.

4. The photovoltaic film of claim 1 wherein the overall thickness of the photovoltaic film is about 25 nm so as to result in a short-circuit current density, J_{SC}, of about 5.3 mA/cm², an open-circuit voltage, V_{oc}, of about 0.81 V, a fill factor, FF, of about 69% and an overall power conversion efficiency, η, of about 2.9%.

5. The photovoltaic film of claim 1 wherein the extracted hot carriers are capable of resulting in an electric field that reduces carrier recombination so as to result in the short-circuit current density between about 4 mA/cm² and about 8 mA/cm².

6. The photovoltaic film of claim 1 wherein the extracted hot carriers are capable of resulting in a multiple excitation generation so as to result in the short-circuit density between about 4 mA/cm² and about 8 mA/cm².

7. The photovoltaic film of claim 1 further comprising:
a first selective energy filter disposed between the p-doped material and the intrinsic region; and
a second selective energy filter disposed between the n-doped material and the intrinsic region.

8. The photovoltaic film of claim 7 wherein the first selective energy filter and the second selective energy filter are quantum dots.

9. The photovoltaic film of claim 1 positioned on at least one of a glass window or a fabric.

10. The photovoltaic film of claim 1 incorporated into a building-integrated photovoltaic module.

11. A solar cell comprising:
an array of nano-coaxial structures, wherein each nano-coaxial structure comprises a metallized nanopillar surrounded by a nanoscopically thin photovoltaic film located adjacent to a side of the nanopillar, and a transparent conducting coating located adjacent to a side of the nanoscopically thin photovoltaic film,
wherein the nanoscopically thin photovoltaic film comprises:
a p-doped region;
an n-doped region; and
an intrinsic region positioned between the p-doped region and the n-doped region,
wherein an overall thickness of the nanoscopically thin photovoltaic film is between about 15 nm to about 30 nm so as to extract hot carriers excited across a band gap,
wherein the extracted hot carriers are capable of resulting in an open circuit voltage, V_{oc}, of the nanoscopically thin photovoltaic film that increases with optical frequency, and
wherein a short-circuit current density, J_{SC}, of each nano-coaxial structure ranges between about 4 mA/cm² and about 8 mA/cm².

12. The solar cell of claim 11 wherein the p-doped region, the n-doped region and the intrinsic region form a hydrogenated amorphous silicon (a-Si:H) junction.

13. The solar cell of claim 11 wherein the overall thickness of the nanoscopically thin photovoltaic film is about 15 nm so as to result in a short-circuit current density, J_{SC}, of about 4.9 mA/cm², an open-circuit voltage, V_{oc}, of about 0.79 V, a fill factor, FF, of about 66% and an overall power conversion efficiency, η, of about 2.6%.

14. The solar cell of claim 11 wherein the overall thickness of the nanoscopically thin photovoltaic film is about 25 nm so as to result in a short-circuit current density, J_{sc}, of about 5.3 mA/cm², an open-circuit voltage, V_{oc}, of about 0.81 V, a fill factor, FF, of about 69% and an overall power conversion efficiency, η, of about 2.9%.

15. The solar cell of claim 11 further comprising:
a first selective energy filter disposed between the p-doped material and the intrinsic region; and
a second selective energy filter disposed between the n-doped material and the intrinsic region.

16. The solar cell of claim 15 wherein the first selective energy filter and the second selective energy filter are quantum dots.

17. A solar panel comprising:
an interconnected assembly of solar cells, wherein at least some of the solar cells in the assembly include one or more layers of a nanoscopically thin photovoltaic film deposited on a substrate, where a transparent conducting oxide layer forms a front electrical contact and a metal layer forms a rear contact,
wherein the nanoscopically thin photovoltaic film comprises:
a p-doped region;
an n-doped region; and
an intrinsic region positioned between the p-doped region and the n-doped region,
wherein an overall thickness of the nanoscopically thin photovoltaic film is between about 15 nm to about 30 nm so as to extract hot carriers excited across a band gap,
wherein the extracted hot carriers are capable of resulting in an open circuit voltage, V_{oc}, of the nanoscopically thin photovoltaic film that increases with optical frequency, and
wherein a short-circuit current density, J_{sc}, of each of the solar cells including the nanoscopically thin photovoltaic film ranges between about 4 mA/cm² and about 8 mA/cm².

18. The solar panel of claim 17 wherein the p-doped region, the n-doped region and the intrinsic region form a hydrogenated amorphous silicon (a-Si:H) junction.

19. The solar panel of claim 17 wherein the overall thickness of the photovoltaic film is about 15 nm so as to result in a short-circuit current density, J_{SC}, of about 4.9 mA/cm², an open-circuit voltage, V_{oc}, of about 0.79 V, a fill factor, FF, of about 66% and an overall power conversion efficiency, η, of about 2.6%.

20. The solar panel of claim 17 wherein the overall thickness of the photovoltaic film is about 25 nm so as to result in a short-circuit current density, J_{SC}, of about 5.3 mA/cm², an open-circuit voltage, V_{oc}, of about 0.81 V, a a fill factor, FF, of about 69% and an overall power conversion efficiency, η, of about 2.9%.

21. The solar panel of claim 17 further comprising:
a first selective energy filter disposed between the p-doped material and the intrinsic region; and
a second selective energy filter disposed between the n-doped material and the intrinsic region.

22. The solar panel of claim 21 wherein the first selective energy filter and the second selective energy filter are quantum dots.
